(19) United States
(12) Patent Application Publication
(10) Pub. No.: US 2024/0194641 A1
(43) Pub. Date: Jun. 13, 2024

(54) SEMICONDUCTOR PACKAGE AND METHOD OF FABRICATING THE SAME

(71) Applicant: Samsung Electronics Co., Ltd., Suwon-si (KR)

(72) Inventors: Chi Woo LEE, Suwon-si (KR); Hyeonjeong HWANG, Suwon-si (KR); Mi Hyae PARK, Suwon-si (KR)

(73) Assignee: Samsung Electronics Co., Ltd., Suwon-si (KR)

(21) Appl. No.: 18/348,011

(22) Filed: Jul. 6, 2023

(30) Foreign Application Priority Data
Dec. 16, 2022 (KR) 10-2022-0177271

(51) Int. Cl. H01L 25/065; H01L 23/00; H01L 23/31; H01L 23/528; H01L 23/538

(52) U.S. Cl. CPC H01L 25/0652; H01L 23/3157; H01L 23/528; H01L 23/5383; H01L 24/08; H01L 24/16; H01L 25/0655; H01L 2224/08155; H01L 2224/16227

(57) ABSTRACT

Disclosed are semiconductor packages and fabrication methods thereof. The semiconductor package includes a substrate, a first semiconductor chip and a second semiconductor chip that are mounted on the substrate, and a bridge chip between a first lateral surface of the first semiconductor chip and a second lateral surface of the second semiconductor chip. The first semiconductor chip and the second semiconductor chip are electrically connected through the bridge chip. The first semiconductor chip includes a first chip pad on the first lateral surface. The bridge chip includes a first connection pad on a first surface of the bridge chip. The first lateral surface of the first semiconductor chip and the first surface of the bridge chip are in contact with each other. The first chip pad and the first connection pad include a same material and are bonded to each other to constitute an integral piece formed.

### CROSS-REFERENCE TO RELATED APPLICATION

This U.S. nonprovisional application claims priority under 35 U.S.C § 119 to Korean Patent Application No. 10-2022-0177271 filed on Dec. 16, 2022 in the Korean Intellectual Property Office, the disclosure of which is hereby incorporated by reference in its entirety.

### BACKGROUND

The present example inventive concepts relate to semiconductor packages and/or methods of fabricating the same.

With the development of electronic industry, electronic products have increasing demands for high performance, high speed, and compact size. To meet the trend, there has recently been developed a packaging technology in which a plurality of semiconductor chips are mounted in a single package.

A semiconductor package is provided to implement an integrated circuit chip to qualify for use in electronic products. Typically, a semiconductor package is configured such that a semiconductor chip is mounted on a printed circuit board (PCB) and bonding wires or bumps are used to electrically connect the semiconductor chip to the printed circuit board. With the recent development of electronic industry, the semiconductor package is variously developed to reach the goal of compact size, small weight, and/or low manufacturing cost. In addition, many kinds of semiconductor packages are appearing with the expansion of their application field such as high-capacity mass storage devices.

### SUMMARY

Some example embodiments of the present example inventive concepts provide a compact-sized semiconductor package and a method of fabricating the same.

Some example embodiments of the present example inventive concepts provide a semiconductor package with improved electrical properties and a method of fabricating the same.

Some example embodiments of the present example inventive concepts provide a semiconductor package with enhanced thermal properties and a method of fabricating the same.

According to an example embodiment of the present inventive concepts, a semiconductor package may include a substrate, a first semiconductor chip and a second semiconductor chip that are mounted on the substrate, and a bridge chip between a first lateral surface of the first semiconductor chip and a second lateral surface of the second semiconductor chip. The first semiconductor chip and the second semiconductor chip may be electrically connected through the bridge chip. The first semiconductor chip may include a first chip pad on the first lateral surface. The bridge chip may include a first connection pad on a first surface of the bridge chip. The first lateral surface of the first semiconductor chip and the first surface of the bridge chip may be in contact with each other. The first chip pad and the first connection pad may include a same material and may be bonded to each other to constitute an integral piece.

According to an example embodiment of the present inventive concepts, a semiconductor package may include a substrate, a chip stack on the substrate, a first semiconductor chip on the substrate and spaced apart from the chip stack, a bridge chip that is interposed between and electrically connects the chip stack and the first semiconductor chip, and a molding layer on the substrate and surrounding the chip stack, the first semiconductor chip, and the bridge chip. The chip stack may include a plurality of second semiconductor chips that are stacked on the substrate. The bridge chip may be in direct contact with the first semiconductor chip and the second semiconductor chips. A lowermost end of the bridge chip may be at a level higher than a level of a top surface of the substrate.

According to an example embodiment of the present inventive concepts, a method of fabricating a semiconductor package may include providing a first semiconductor chip and a second semiconductor chip, forming a bridge chip, placing the first semiconductor chip on a carrier substrate to allow a first lateral surface of the first semiconductor chip to contact the carrier substrate, bonding the bridge chip to a second lateral surface of the first semiconductor chip, the second lateral surface being opposite to the first lateral surface, and a first primary surface of the bridge chip being in contact with the second lateral surface, bonding the second semiconductor chip to a second primary surface of the bridge chip, the second primary surface being opposite to the first primary surface, and a third lateral surface of the second semiconductor chip being in contact with the second primary surface, removing the carrier substrate, and mounting the first semiconductor chip and the second semiconductor chip on a substrate.

According to an example embodiment of the present inventive concepts, a semiconductor package may include a substrate, a first semiconductor chip on the substrate, the first semiconductor chip including a first circuit layer on a bottom surface of the first semiconductor chip and having a first integrated circuit of the first semiconductor chip, and a first lateral wiring layer on a first lateral surface of the first semiconductor chip and connected to the first circuit layer, a second semiconductor chip on the substrate, the second semiconductor chip including a second circuit layer on a bottom surface of the second semiconductor chip and having a second integrated circuit of the second semiconductor chip, and a second lateral wiring layer on a second lateral surface of the second semiconductor chip and connected to the second circuit layer, a bridge chip including a first primary surface and a second primary surface, the first primary surface bonded to the first lateral wiring layer and the second primary surface bonded to the second lateral wiring layer, and a molding layer on the substrate and surrounding the first semiconductor chip, the second semiconductor chip, and the bridge chip. The first semiconductor chip and the second semiconductor chip may be electrically connected through the bridge chip.

### BRIEF DESCRIPTION OF THE DRAWINGS

FIG. 1 illustrates a cross-sectional view showing a semiconductor package according to an example embodiment of the present inventive concepts.

FIGS. 2 and 3 illustrate enlarged views showing section A of FIG. 1 according to some example embodiment.

FIG. 4 illustrates an enlarged view showing section B of FIG. 2, according to an example embodiment.

FIGS. 5 and 6 illustrate cross-sectional views showing a bridge chip of a semiconductor package according to some example embodiments of the present inventive concepts.

FIG. 7 illustrates a cross-sectional view showing a semiconductor package according to an example embodiment of the present inventive concepts.

FIG. 8 illustrates an enlarged view showing section C of FIG. 7 according to an example embodiment.

FIG. 9 illustrates a cross-sectional view showing a semiconductor package according to an example embodiment of the present inventive concepts.

FIG. 10 illustrates an enlarged view showing section D of FIG. 9.

FIG. 11 illustrates a cross-sectional view showing a semiconductor package according to an example embodiment of the present inventive concepts.

FIGS. 12 and 13 illustrate enlarged views showing section E of FIG. 11 according to some example embodiments.

FIG. 14 illustrates a cross-sectional view showing a semiconductor package according to an example embodiment of the present inventive concepts.

FIGS. 15 and 16 illustrate enlarged views showing section F of FIG. 14 according to some example embodiments.

FIGS. 17 to 24 illustrate cross-sectional views showing a method of fabricating a semiconductor package according to an example embodiment of the present inventive concepts.

### DETAILED DESCRIPTION

The following will now describe a semiconductor package according to the present inventive concepts with reference to the accompanying drawings.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

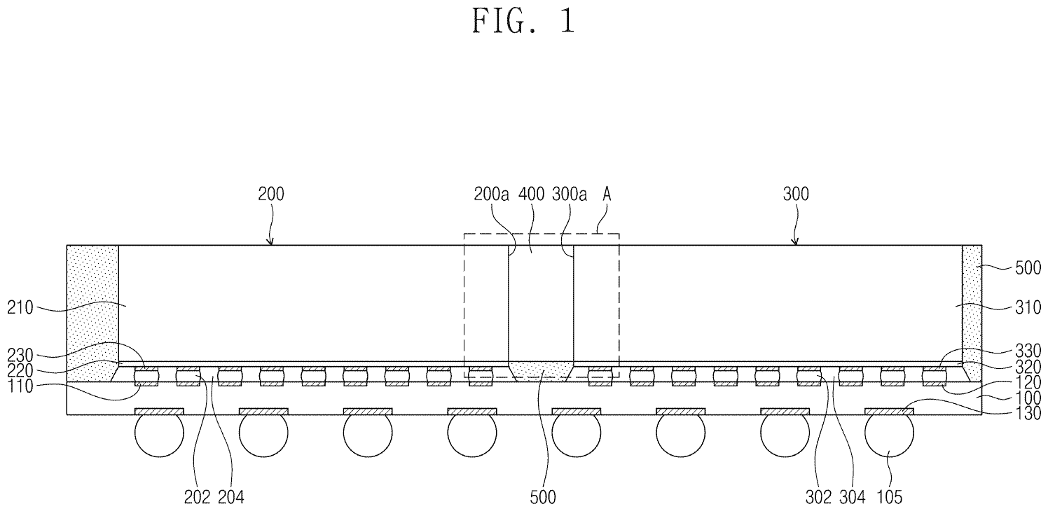

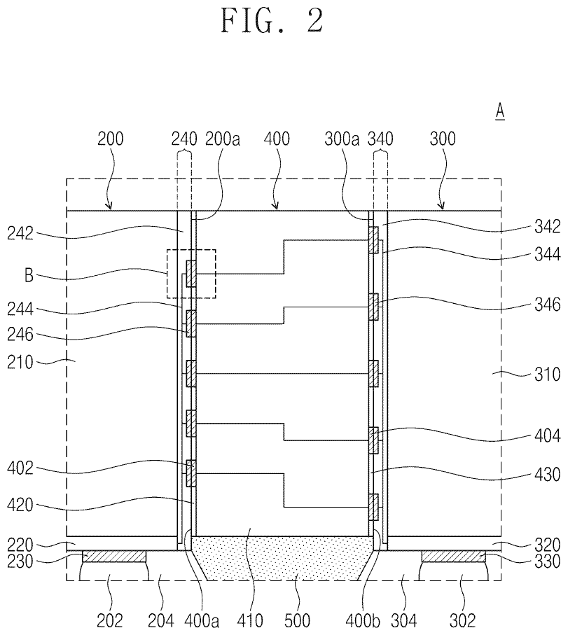

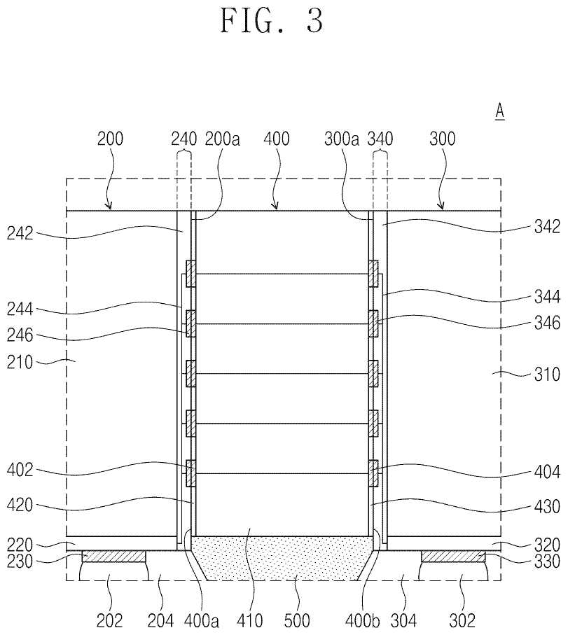

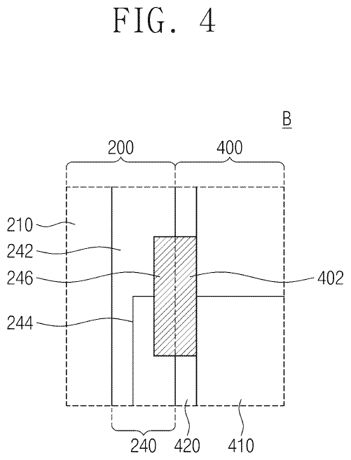

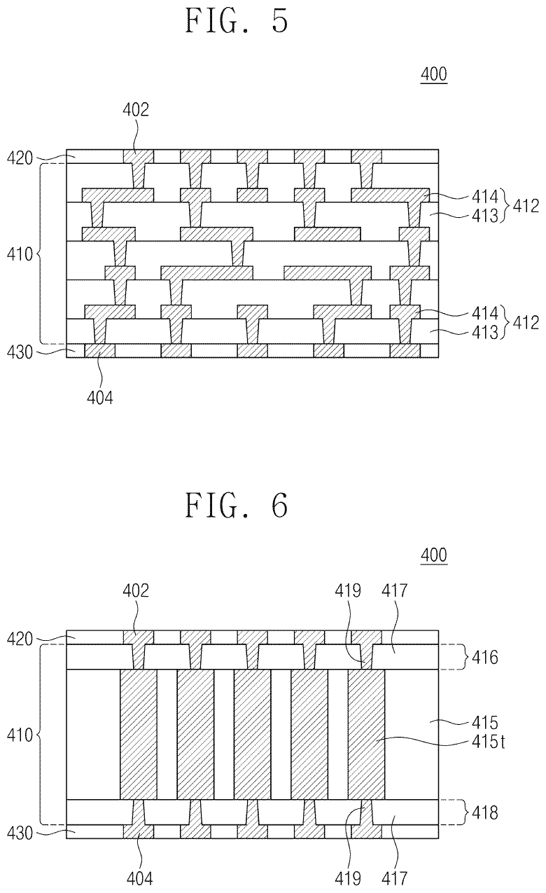

FIG. 1 illustrates a cross-sectional view showing a semiconductor package according to an example embodiment of the present inventive concepts. FIGS. 2 and 3 illustrate enlarged views showing section A of FIG. 1 according to an example embodiment. FIG. 4 illustrates an enlarged view showing section B of FIG. 2 according to some example embodiments. FIGS. 5 and 6 illustrate cross-sectional views showing a bridge chip of a semiconductor package according to some example embodiments of the present inventive concepts.

Referring to FIGS. 1 to 4, a substrate 100 may be provided. The substrate 100 may be a package substrate to mount a semiconductor package on an external apparatus, a motherboard, or another substrate. In some example embodiments, the substrate 100 may be an interposer to redistribute semiconductor chips of a semiconductor package or to connect semiconductor chips to a package substrate of a semiconductor package. For example, the substrate 100 may be a printed circuit board having a signal pattern or a redistribution substrate having a plurality of wiring layers. The substrate 100 may have first substrate pads 110 and second substrate pads 120 provided on a top surface of the substrate 100, and may also have third substrate pads 130 provided on a bottom surface of the substrate 100. The first substrate pads 110 and the second substrate pads 120 may be electrically connected to the third substrate pads 130 through internal connection lines of the substrate 100. The first substrate pads 110 and the second substrate pads 120 may not be electrically connected through the wiring lines in the substrate 100. An electrical connection between a first semiconductor chip 200 mounted on the first substrate pads 110 and a second semiconductor chip 300 mounted on the second substrate pads 120 may be achieved by a separate component such as a bridge chip 400, which will be further discussed in detail below.

External terminals 105 may be disposed below the substrate 100. On the bottom surface of the substrate 100, the external terminals 105 may be coupled to the third substrate pads 130 of the substrate 100. The external terminals 105 may include solder balls or solder bumps, and based on the type and arrangement of the external terminals 105, a semiconductor package may be provided in the form of one of a ball grid array (BGA) type, a fine ball grid array (FBGA) type, and a land grid array (LGA) type.

The first semiconductor chip 200 may be disposed on the substrate 100. The first semiconductor chip 200 may include a first semiconductor substrate 210, a first circuit layer 220, a first lower pad 230, and a first lateral wiring layer 240.

The first semiconductor substrate 210 may include a semiconductor material. For example, the first semiconductor substrate 210 may be a monocrystalline silicon (Si) substrate. The first semiconductor substrate 210 may have a top surface and a bottom surface that are opposite to each other. The bottom surface of the first semiconductor substrate 210 may be a front surface of the first semiconductor substrate 210, and the top surface of the first semiconductor substrate 210 may be a rear surface of the first semiconductor substrate 210. For example, the bottom surface of the first semiconductor substrate 210 may be an active surface, and the top surface of the first semiconductor substrate 210 may be an inactive surface.

The first circuit layer 220 may be provided on the bottom surface of the first semiconductor substrate 210. The first circuit layer 220 may include an integrated circuit. For example, the integrated circuit may include a wiring pattern, a dielectric pattern, and an electronic device (e.g., transistor) that are formed on the bottom surface of the first semiconductor substrate 210. The first circuit layer 220 may include a memory circuit. For example, the first semiconductor chip 200 may be a memory chip. For another example, the first circuit layer 220 may include a logic circuit.

The first lower pad 230 may be disposed on the bottom surface of the first semiconductor substrate 210. The first lower pad 230 may be disposed on a bottom surface of the first circuit layer 220. The first lower pad 230 may be coupled to the first circuit layer 220. The first lower pad 230 may be provided in plural. The first lower pad 230 may be a front pad of the first semiconductor chip 200. The first lower pad 230 may include a metallic material, such as copper (Cu), aluminum (Al), and/or nickel (Ni).

Although not shown, a first redistribution layer may be provided between the first lower pad 230 and the first circuit layer 220. The first redistribution layer may cover the bottom surface of the first circuit layer 220. The first redistribution layer may be provided to redistribute the first circuit layer 220 and the first lower pad 230 and/or to protect the first circuit layer 220. The first redistribution layer may include a dielectric layer and a redistribution pattern buried in the dielectric layer. The dielectric layer may cover the bottom surface of the first circuit layer 220. The dielectric layer may be a multiple layer in which a silicon nitride (SiN) layer and a silicon oxide (SiO) layer overlap each other. The redistribution pattern may be disposed in the dielectric layer. The redistribution pattern may electrically connect the first circuit layer 220 and the first lower pad 230 to each other. The redistribution pattern may include a metallic material, such as copper (Cu), aluminum (Al), and/or nickel (Ni).

The first lateral wiring layer 240 may be disposed on a first lateral surface 200a of the first semiconductor chip 200. The first lateral wiring layer 240 may cover a lateral surface of the first semiconductor substrate 210 and a lateral surface of the first circuit layer 220. The first lateral wiring layer 240 may include a first dielectric layer 242 and a first wiring pattern 244 buried in the first dielectric layer 242.

The first dielectric layer 242 may cover the lateral surface of the first semiconductor substrate 210 and the lateral surface of the first circuit layer 220. The first dielectric layer 242 may be a multiple layer in which a silicon nitride (SiN) layer and a silicon oxide (SiO) layer overlap each other.

The first wiring pattern 244 may be disposed in the first dielectric layer 242. The first wiring pattern 244 may be provided to expand or redistribute an electrical circuit of the first circuit layer 220 onto the first lateral surface 200a of the first semiconductor chip 200. The first wiring pattern 244 may be electrically connected to the first circuit layer 220. The first wiring pattern 244 may include a metallic material, such as copper (Cu), aluminum (Al), and/or nickel (Ni).

The first lateral wiring layer 240 may further include a first chip pad 246. The first chip pad 246 may be disposed in the first dielectric layer 242 while being exposed on one surface of the first dielectric layer 242. In this case, the one surface of the first dielectric layer 242 through which the first chip pad 246 is exposed may correspond to the first lateral surface 200a of the first semiconductor chip 200. For example, the first chip pad 246 may be exposed on the first lateral surface 200a of the first semiconductor chip 200. The one surface of the first dielectric layer 242 may be coplanar with one surface of the first chip pad 246, and the surfaces of the first dielectric layer 242 and the first chip pad 246 may be substantially flat. The first chip pad 246 may be connected to the first wiring pattern 244 of the first lateral wiring layer 240. The first wiring pattern 244 may electrically connect the first chip pad 246 and the first circuit layer 220 to each other. The first chip pad 246 may be provided in plural.

The first semiconductor chip 200 may be mounted on the substrate 100. For example, the first semiconductor chip 200 may be disposed on the substrate 100. The first semiconductor chip 200 may be disposed in a face-down state on the substrate 100. The first substrate pads 110 of the substrate 100 may be vertically aligned with the first lower pads 230 of the first semiconductor chip 200.

The first semiconductor chip 200 may be flip-chip mounted on the substrate 100. For example, first connection terminals 202 may be provided on the first lower pads 230. The first semiconductor chip 200 may be aligned on the substrate 100 to allow the first connection terminals 202 to face toward top surfaces of the first substrate pads 110. The first connection terminals 202 may connect the first substrate pads 110 to the first lower pads 230. Each of the first connection terminals 202 may connect one of the first substrate pads 110 to a corresponding one of the first lower pads 230. The first connection terminals 202 may include solder balls or solder bumps. The first connection terminals 202 may be an alloy that includes at least one selected from tin (Sn), silver (Ag), copper (Cu), nickel (Ni), bismuth (Bi), indium (In), antimony (Sb), and cerium (Ce).

A first underfill layer 204 may be provided between the substrate 100 and the first semiconductor chip 200. The first underfill layer 204 may fill a space between the substrate 100 and the first semiconductor chip 200. The first underfill layer 204 may surround the first connection terminals 202.

The second semiconductor chip 300 may be disposed on the substrate 100. On the substrate 100, the second semiconductor chip 300 may be disposed horizontally spaced apart from the first semiconductor chip 200. For example, the second semiconductor chip 300 may be positioned on the first lateral surface 200a of the first semiconductor chip 200. The second semiconductor chip 300 may be spaced apart from the first lateral surface 200a of the first semiconductor chip 200. The second semiconductor chip 300 may include a second semiconductor substrate 310, a second circuit layer 320, a second lower pad 330, and a second lateral wiring layer 340.

The second semiconductor substrate 310 may include a semiconductor material. For example, the second semiconductor substrate 310 may be a monocrystalline silicon (Si) substrate. The second semiconductor substrate 310 may have a top surface and a bottom surface that are opposite to each other. The bottom surface of the second semiconductor substrate 310 may be a front surface of the second semiconductor substrate 310, and the top surface of the second semiconductor substrate 310 may be a rear surface of the second semiconductor substrate 310. For example, the bottom surface of the second semiconductor substrate 310 may be an active surface, and the top surface of the second semiconductor substrate 310 may be an inactive surface.

The second circuit layer 320 may be provided on the bottom surface of the second semiconductor substrate 310. The second circuit layer 320 may include an integrated circuit. For example, the integrated circuit may include a wiring pattern, a dielectric pattern, and an electronic device (e.g., transistor) that are formed on the bottom surface of the second semiconductor substrate 310. The second circuit layer 320 may include a logic circuit. For example, the second semiconductor chip 300 may be a logic chip. For example, the second circuit layer 320 may include a memory circuit.

The second lower pad 330 may be disposed on the bottom surface of the second semiconductor substrate 310. The second lower pad 330 may be disposed on a bottom surface of the second circuit layer 320. The second lower pad 330 may be coupled to the second circuit layer 320. The second lower pad 330 may be provided in plural. The second lower pad 330 may be a front pad of the second semiconductor chip 300. The second lower pad 330 may include a metallic material, such as copper (Cu), aluminum (Al), and/or nickel (Ni).

Although not shown, a second redistribution layer may be provided between the second lower pad 330 and the second circuit layer 320. The second redistribution layer may cover the bottom surface of the second circuit layer 320. The second redistribution layer may be provided to redistribute the second circuit layer 320 and the second lower pad 330 and/or to protect the second circuit layer 320. The second redistribution layer may include a dielectric layer and a redistribution pattern buried in the dielectric layer. The dielectric layer may cover the bottom surface of the second circuit layer 320. The dielectric layer may be a multiple layer in which a silicon nitride (SiN) layer and a silicon oxide (SiO) layer overlap each other. The redistribution pattern may be disposed in the dielectric layer. The redistribution pattern may electrically connect the second circuit layer 320 and the second lower pad 330 to each other. The redistribution pattern may include a metallic material, such as copper (Cu), aluminum (Al), and/or nickel (Ni).

The second lateral wiring layer 340 may be disposed on a second lateral surface 300a of the second semiconductor chip 300. The second lateral surface 300a of the second semiconductor chip 300 may be a lateral surface of the second semiconductor chip 300, which lateral surface is directed toward the first lateral surface 200a of the first semiconductor chip 200. For example, the first lateral surface 200a of the first semiconductor chip 200 may face the second lateral surface 300a of the second semiconductor chip 300. The second lateral wiring layer 340 may cover a lateral surface of the second semiconductor substrate 310 and a lateral surface of the second circuit layer 320. The second lateral wiring layer 340 may include a second dielectric layer 342 and a second wiring pattern 344 buried in the second dielectric layer 342.

The second dielectric layer 342 may cover the lateral surface of the second semiconductor substrate 310 and the lateral surface of the second circuit layer 320. The second dielectric layer 342 may be a multiple layer in which a silicon nitride (SiN) layer and a silicon oxide (SiO) layer overlap each other.

The second wiring pattern 344 may be disposed in the second dielectric layer 342. The second wiring pattern 344 may be provided to expand or redistribute an electrical circuit of the second circuit layer 320 onto the second lateral surface 300a of the second semiconductor chip 300. The second wiring pattern 344 may be electrically connected to the second circuit layer 320. The second wiring pattern 344 may include a metallic material, such as copper (Cu), aluminum (Al), and/or nickel (Ni).

The second lateral wiring layer 340 may further include a second chip pad 346. The second chip pad 346 may be disposed in the second dielectric layer 342 while being exposed on one surface of the second dielectric layer 342. In this case, the one surface of the second dielectric layer 342 through which the second chip pad 346 is exposed may correspond to the second lateral surface 300a of the second semiconductor chip 300. For example, the second chip pad 346 may be exposed on the second lateral surface 300a of the second semiconductor chip 300. The one surface of the second dielectric layer 342 may be coplanar with one surface of the second chip pad 346, and the surfaces of the second dielectric layer 342 and the second chip pad 346 may be substantially flat. The second chip pad 346 may be connected to the second wiring pattern 344 of the second lateral wiring layer 340. The second wiring pattern 344 may electrically connect the second chip pad 346 and the second circuit layer 320 to each other. The second chip pad 346 may be provided in plural.

The second semiconductor chip 300 may be mounted on the substrate 100. For example, the second semiconductor chip 300 may be disposed on the substrate 100. The second semiconductor chip 300 may be disposed in a face-down state on the substrate 100. The second substrate pads 120 of the substrate 100 may be vertically aligned with the second lower pads 330 of the second semiconductor chip 300.

The second semiconductor chip 300 may be flip-chip mounted on the substrate 100. For example, second connection terminals 302 may be provided on the second lower pads 330. The second semiconductor chip 300 may be aligned on the substrate 100 to allow the second connection terminals 302 to face toward top surfaces of the second substrate pads 120. The second connection terminals 302 may connect the second substrate pads 120 to the second lower pads 330. Each of the second connection terminals 302 may connect one of the second substrate pads 120 to a corresponding one of the second lower pads 330. The second connection terminals 302 may include solder balls or solder bumps. The second connection terminals 302 may be an alloy that includes at least one selected from tin (Sn), silver (Ag), copper (Cu), nickel (Ni), bismuth (Bi), indium (In), antimony (Sb), and cerium (Ce).

A second underfill layer 304 may be provided between the substrate 100 and the second semiconductor chip 300. The second underfill layer 304 may fill a space between the substrate 100 and the second semiconductor chip 300. The second underfill layer 304 may surround the second connection terminals 302.

The bridge chip 400 may be provided on the substrate 100. The bridge chip 400 may be interposed between the first semiconductor chip 200 and the second semiconductor chip 300. For example, the bridge chip 400 may be interposed between the first lateral surface 200a of the first semiconductor chip 200 and the second lateral surface 300a of the second semiconductor chip 300. In this case, the bridge chip 400 may be in contact with both of the first lateral surface 200a of the first semiconductor chip 200 and the second lateral surface 300a of the second semiconductor chip 300. The bridge chip 400 may have a first surface 400a in contact with the first lateral surface 200a and a second surface 400b in contact with the second lateral surface 300a. The first surface 400a and the second surface 400b of the bridge chip 400 may respectively be a front surface and a rear surface of the bridge chip 400. A top end of the bridge chip 400 may be located at the same level as that of a top surface of the first semiconductor chip 200 and that of a top surface of the second semiconductor chip 300. However, the present inventive concepts are not limited thereto, and the top end of the bridge chip 400 may be located at a level higher than those of the top surfaces of the first and second semiconductor chips 200 and 300, or lower than those of the top surfaces of the first and second semiconductor chips 200 and 300 and higher than that of an uppermost one of the first and second chip pads 246 and 346. A bottom end of the bridge chip 400 may be spaced apart from the substrate 100. For example, the bottom end of the bridge chip 400 may be located at a level the same as or higher than that of a bottom surface of the first semiconductor chip 200 and that of a bottom surface of the second semiconductor chip 300. The bottom end of the bridge chip 400 may be located at a lower level than that of a lowermost one of the first and second chip pads 246 and 346. The bridge chip 400 may have a wiring section 410, a first protection layer 420 and a second protection layer 430 that cover opposite surfaces of the wiring section 410, a first connection pad 402, and a second connection pad 404.

The wiring section 410 may extend parallel to the first lateral surface 200a of the first semiconductor chip 200 and the second lateral surface 300a of the second semiconductor chip 300. The following will describe in detail a shape of the wiring section 410 and an electrical connection relationship in the bridge chip 400.

The wiring section 410 may be provided with the first connection pad 402 on its first primary surface directed toward the first semiconductor chip 200. The first connection pad 402 may be electrically connected to an internal connection line of the wiring section 410. The first connection pad 402 may be provided in plural.

The wiring section 410 may be provided with the first protection layer 420 on the first primary surface directed toward the first semiconductor chip 200. The first protection layer 420 may surround the first connection pads 402 while covering the first primary surface of the wiring section 410. The first protection layer 420 may expose surfaces of the first connection pads 402. For example, on the first surface 400a of the bridge chip 400, one surface of the first protection layer 420 may be substantially flat and coplanar with the surfaces of the first connection pads 402.

The wiring section 410 may be provided with the second connection pad 404 on its second primary surface directed toward the second semiconductor chip 300. The second connection pad 404 may be electrically connected to an internal connection line of the wiring section 410. The second connection pad 404 may be provided in plural. The second connection pads 404 may be electrically connected through the wiring section 410 to the first connection pads 402. As shown in FIG. 2, when viewed in a direction from the first surface 400a toward the second surface 400b of the bridge chip 400, the first connection pads 402 may not be aligned with the second connection pads 404. For example, the first connection pads 402 and the second connection pads 404 may be redistributed through the wiring section 410. In some example embodiments, as shown in FIG. 3, when viewed in a direction from the first surface 400a toward the second surface 400b of the bridge chip 400, the first connection pads 402 may be aligned with the second connection pads 404.

The wiring section 410 may be provided with the second protection layer 430 on the second primary surface directed toward the second semiconductor chip 300. The second protection layer 430 may surround the second connection pads 404 while covering the second primary surface of the wiring section 410. The second protection layer 430 may expose surfaces of the second connection pads 404. For example, on the second surface 400b of the bridge chip 400, one surface of the second protection layer 430 may be substantially flat and coplanar with the surfaces of the second connection pads 404.

The bridge chip 400 may be bonded to the first semiconductor chip 200. For example, the first surface 400a of the bridge chip 400 may be in contact with the first lateral surface 200a of the first semiconductor chip 200. The first connection pads 402 may be connected to the first chip pads 246. Each of the first connection pads 402 may be bonded to one of the first chip pads 246. As shown in FIG. 4, the first connection pad 402 and the first chip pad 246 may constitute an intermetallic hybrid bonding. In this description, the term “hybrid bonding” may denote a bonding in which two components of the same kind are merged at an interface therebetween. For example, the first connection pad 402 and the first chip pad 246 that are bonded to each other may have a continuous configuration, and an invisible interface may be provided between the first connection pad 402 and the first chip pad 246. The first connection pad 402 and the first chip pad 246 may be formed of the same material, and no interface may be present between the first connection pad 402 and the first chip pad 246. One of the first connection pads 402 and a corresponding one of the first chip pads 246 may be provided as one component. For example, the first connection pad 402 and the first chip pad 246 may be connected to form a single unitary piece (e.g., an integral piece).

On an interface between the first semiconductor chip 200 and the bridge chip 400, the first dielectric layer 242 of the first lateral wiring layer 240 in the first semiconductor chip 200 may be bonded to the first protection layer 420 of the bridge chip 400. In this case, the first dielectric layer 242 and the first protection layer 420 may constitute a hybrid bonding of oxide, nitride, or oxynitride. For example, the first dielectric layer 242 and the first protection layer 420 that are bonded to each other may have a continuous configuration, and an invisible interface may be provided between the first dielectric layer 242 and the first protection layer 420. In this sense, the first dielectric layer 242 and the first protection layer 420 may be provided as one component. The present inventive concepts, however, are not limited thereto. The first dielectric layer 242 and the first protection layer 420 may be formed of different materials from each other. The first dielectric layer 242 and the first protection layer 420 may have no continuous configuration, and a visible interface may be provided between the first dielectric layer 242 and the first protection layer 420.

The bridge chip 400 may be bonded to the second semiconductor chip 300. For example, the second surface 400b of the bridge chip 400 may be in contact with the second lateral surface 300a of the second semiconductor chip 300. The second connection pads 404 may be connected to the second chip pads 346. Each of the second connection pads 404 may be bonded to a corresponding one of the second chip pads 346. In this case, the second connection pad 404 and the second chip pad 346 may constitute an intermetallic hybrid bonding. For example, the second connection pad 404 and the second chip pad 346 that are bonded to each other may have a continuous configuration, and an invisible interface may be provided between the second connection pad 404 and the second chip pad 346. The second connection pad 404 and the second chip pad 346 may be formed of the same material, and no interface may be present between the second connection pad 404 and the second chip pad 346. One of the second connection pads 404 and a corresponding one of the second chip pads 346 may be provided as one component. For example, the second connection pad 404 and the second chip pad 346 may be connected to form a single unitary piece (e.g., an integral piece).

On an interface between the second semiconductor chip 300 and the bridge chip 400, the second dielectric layer 342 of the second lateral wiring layer 340 in the second semiconductor chip 300 may be bonded to the second protection layer 430 of the bridge chip 400. In this case, the second dielectric layer 342 and the second protection layer 430 may constitute a hybrid bonding of oxide, nitride, or oxynitride. For example, the second dielectric layer 342 and the second protection layer 430 that are bonded to each other may have a continuous configuration, and an invisible interface may be provided between the second dielectric layer 342 and the second protection layer 430. In this sense, the second dielectric layer 342 and the second protection layer 430 may be provided as one component. The present inventive concepts, however, are not limited thereto. The second dielectric layer 342 and the second protection layer 430 may be formed of different materials from each other. The second dielectric layer 342 and the second protection layer 430 may have no continuous configuration, and a visible interface may be provided between the second dielectric layer 342 and the second protection layer 430.

The first semiconductor chip 200 and the second semiconductor chip 300 may be electrically connected to each other through the first lateral wiring layer 240 of the first semiconductor chip 200, the bridge chip 400, and the second lateral wiring layer 340 of the second semiconductor chip 300. For example, the first chip pads 246 of the first semiconductor chip 200 may be electrically connected through the first connection pads 402, the wiring section 410, and the second connection pads 404 to the second chip pads 346 of the second semiconductor chip 300. The wiring section 410 may electrically connect and redistribute the first connection pads 402 and the second connection pads 404.

As shown in FIG. 5, the bridge chip 400 may be a substrate for redistribution. For example, the wiring section 410 of the bridge chip 400 may have a plurality of wiring layers. In FIG. 5, for convenience of description, the bridge chip 400 is shown rotated at an angle of 90 degrees. A configuration of the wiring section 410 in the bridge chip 400 will be described below based on the example embodiment of FIG. 5. The wiring layers 412 may be stacked on each other. In this configuration, as shown in FIGS. 1 to 3, the wiring layers 412 may be stacked in a direction from the first lateral surface 200a of the first semiconductor chip 200 toward the second lateral surface 300a of the second semiconductor chip 300. Each of the wiring layers 412 may include a dielectric pattern 413 and a wiring pattern 414 in the dielectric pattern 413. The wiring pattern 414 of one of the wiring layers 412 may be electrically connected to the wiring pattern 414 of a neighboring one (e.g., a vertically neighboring one) of the wiring layers 412.

The dielectric pattern 413 may include a dielectric polymer or a photo-imageable dielectric (PID). For example, the photo-imageable dielectric may include at least one selected from photosensitive polyimide (PI), polybenzoxazole (PBO), phenolic polymers, and benzocyclobutene polymers. In some example embodiments, the dielectric pattern 413 may include a dielectric material. For example, the dielectric pattern 413 may include silicon oxide (SiO), silicon nitride (SiN), silicon oxynitride (SiON), or dielectric polymers.

The wiring pattern 414 may be provided on the dielectric pattern 413. The wiring pattern 414 may horizontally extend on the dielectric pattern 413. The wiring pattern 414 may be provided on a top surface of the dielectric pattern 413. The wiring pattern 414 may protrude onto the top surface of the dielectric pattern 413. The wiring pattern 414 on the dielectric pattern 413 may be covered with another dielectric pattern 413 that overlies the wiring pattern 414. The wiring pattern 414 may be a component for horizontal redistribution. The wiring pattern 414 of an uppermost wiring layer 412 may serve as the first connection pads 402 of the bridge chip 400. For example, a portion of the wiring pattern 414 of the uppermost wiring layer 412 may be the first connection pads 402, and on the uppermost wiring layer 412, the first protection layer 420 may surround the first connection pads 402. The wiring pattern 414 may include a conductive material. For example, the wiring pattern 414 may include metal, such as copper (Cu).

The wiring pattern 414 may have a damascene structure. For example, the wiring pattern 414 may have a via protruding downwards. The via may be a component for vertical connection between the wiring patterns 414 of neighboring wiring layers 412 (e.g., vertically neighboring wiring layers 412). In some example embodiments, the via may be a component for connection between the second connection pad 404 and the wiring pattern 414 of a lowermost wiring layer 412. For example, the via may protrude downwards through the dielectric pattern 413 to be coupled to a top surface of the wiring pattern 414 included in another wiring layer 412 that underlies the via. For another example, the via may penetrate downwards through a lowermost dielectric pattern 413 to be coupled to a top surface of the second connection pad 404. An upper portion of the wiring pattern 414 positioned on the dielectric pattern 413 may be a head part used as a horizontal connection line or pad, and the via of the wiring pattern 414 may be a tail part. The wiring pattern 414 may be shaped like T in a cross-section.

The bridge chip 400 may be provided as discussed above. The bridge chip 400 of FIG. 5 may correspond to the bridge chip 400 discussed with reference to FIG. 2 or 3.

Although not shown, a barrier layer may be interposed between the dielectric pattern 413 and the wiring pattern 414. The barrier layer may surround the head and tail parts of the wiring pattern 414. The barrier layer may include titanium (Ti), tantalum (Ta), titanium nitride (TiN), or tantalum nitride (TaN).

According to some example embodiments, the wiring section 410 may include a core layer 415, and may also include a first buildup portion 416 and a second buildup portion 418 that are on opposite surfaces of the core layer 415, respectively. In FIG. 6, for convenience of description, the bridge chip 400 is shown rotated at an angle of 90 degrees. A configuration of the wiring section 410 in the bridge chip 400 will be described below based on the example embodiment of FIG. 6.

The core layer 415 may extend in one direction. For example, the core layer 415 may extend in a direction parallel to the first lateral surface 200a of the first semiconductor chip 200 or the second lateral surface 300a of the second semiconductor chip 300. The core layer 415 with one core pattern is discussed by way of example, but the present inventive concepts are not limited thereto. According to some example embodiments, the core layer 415 may include two or more core patterns. The core layer 415 may include a dielectric material. For example, the core layer 415 may include one of glass fiber, ceramic plates, epoxy, and resin. For another example, the core layer 415 may include one selected from stainless steels, aluminum (Al), nickel (Ni), magnesium (Mg), zinc (Zn), tantalum (Ta), and any combination thereof.

The core layer 415 may have a vertical connection terminal 415t that vertically penetrates the core layer 415. The vertical connection terminal 415t may electrically connect the first buildup portion 416 and the second buildup portion 418 to each other. The vertical connection terminal 415t may be provided in plural.

The first buildup portion 416 and the second buildup portion 418 may cover the opposite surfaces of the core layer 415. The core layer 415 may have one surface directed toward the first lateral surface 200a of the first semiconductor chip 200, and the first buildup portion 416 may be in contact with the one surface of the core layer 415. The core layer 415 may have another surface directed toward the second lateral surface 300a of the second semiconductor chip 300, and the second buildup portion 418 may be in contact with the another surface of the core layer 415.

Each of the first and second buildup portions 416 and 418 may include a dielectric pattern 417 and a wiring pattern 419 that are sequentially stacked on a corresponding surface of the core layer 415. The dielectric pattern 417 may include prepreg, Ajinomoto build-up film (ABF), flame retardant 4 (FR-4), or bismaleimide triazine (BT). The wiring pattern 419 may include a circuit pattern. The wiring pattern 419 of the first buildup portion 416 may be used as a connection pattern for connection between the vertical connection terminals 415t and the first connection pads 402. The wiring pattern 419 of the second buildup portion 418 may be used as a connection pattern for connection between the vertical connection terminals 415t and the second connection pads 404. The wiring pattern 419 of the first buildup portion 416 may protrude onto one surface of the dielectric pattern 417, and on the dielectric pattern 417, the first protection layer 420 may surround a head part of the wiring pattern 419. The head part of the wiring pattern 419 of the first buildup portion 416 may serve as the first connection pads 402 of the bridge chip 400. The wiring pattern 419 of the second buildup portion 418 may protrude onto one surface of the dielectric pattern 417, and on the dielectric pattern 417, the second protection layer 430 may surround a head part of the wiring pattern 419. The head part of the wiring pattern 419 of the second buildup portion 418 may serve as the second connection pads 404 of the bridge chip 400. The wiring pattern 419 may include one selected from copper (Cu), aluminum (Al), tin (Sn), gold (Au), nickel (Ni), lead (Pb), titanium (Ti), and any combination thereof. FIG. 6 depicts one-layered first buildup portion 416 and one-layered second buildup portion 418, but the present inventive concepts are not limited thereto. Each of the first and second buildup portions 416 and 418 may be provided as a plurality of wiring layers.

The bridge chip 400 may be provided as discussed above. The bridge chip 400 of FIG. 6 may correspond to the bridge chip 400 discussed with reference to FIG. 3.

According to some example embodiments, the bridge chip 400 may further include dummy patterns that are electrically insulated from internal connection lines through which the first connection pads 402 and the second connection pads 404 are connected in the wiring section 410. The dummy patterns may extend in a direction away from the top surface of the substrate 100. Heat transferred from the first and second semiconductor chips 200 and 300 may be discharged through the dummy patterns toward an upper side of the bridge chip 400.

According to some example embodiments, the bridge chip 400 may further include a passive device electrically connected to internal connection lines through which the first connection pads 402 and the second connection pads 404 are connected in the wiring section 410. For example, the passive device may include a resistor, a capacitor, or an inductor.

According to some example embodiments of the present inventive concepts, an electrical connection between the first semiconductor chip 200 and the second semiconductor chip 300 may be accomplished not through the substrate 100, but through the bridge chip 400 that is interposed between and directly bonded to the first semiconductor chip 200 and the second semiconductor chip 300. Therefore, a length of the electrical connection between the first semiconductor chip 200 and the second semiconductor chip 300 may be reduced, and electrical properties of a semiconductor package may be improved. The substrate 100 may include no connection line that connects the first semiconductor chip 200 and the second semiconductor chip 300 to each other, and thus the substrate 100 may have a reduced thickness. A semiconductor package may thus have a smaller thickness and a more compact size.

In addition, as the bridge chip 400 is interposed between the first semiconductor chip 200 and the second semiconductor chip 300, the bridge chip 400 may block heat generated from the first semiconductor chip 200 or the second semiconductor chip 300. Thus, the first semiconductor chip 200 and the second semiconductor chip 300 may not be affected by the heat generated from the second semiconductor chip 300 or the first semiconductor chip 200, and a semiconductor package may have improved thermal stability and enhanced driving stability.

Moreover, because both of the first and second semiconductor chips 200 and 300 are directly bonded to the bridge chip 400, the first semiconductor chip 200 and the second semiconductor chip 300 may be firmly bonded to each other. Accordingly, a semiconductor package may increase in structural stability.

Referring still to FIGS. 1 to 4, a molding layer 500 may be provided on the substrate 100. On the top surface of the substrate 100, the molding layer 500 may surround the first semiconductor chip 200, the second semiconductor chip 300, and the bridge chip 400. The molding layer 500 may fill a space between the substrate 100 and the bridge chip 400. The top surface of each of the first and second semiconductor chips 200 and 300 may be exposed on a top surface of the molding layer 500. In some example embodiments, the molding layer 500 may completely cover the first semiconductor chip 200 and the second semiconductor chip 300. The molding layer 500 may include a dielectric material. For example, the molding layer 500 may include an epoxy molding compound (EMC).

In the example embodiments that follow, a detailed description of technical features repetitive to those discussed above with reference to FIGS. 1 to 6 will be omitted, and a difference thereof will be discussed in detail. The same reference numerals may be allocated to the same components as those of the semiconductor package discussed above according to some example embodiments of the present inventive concepts.

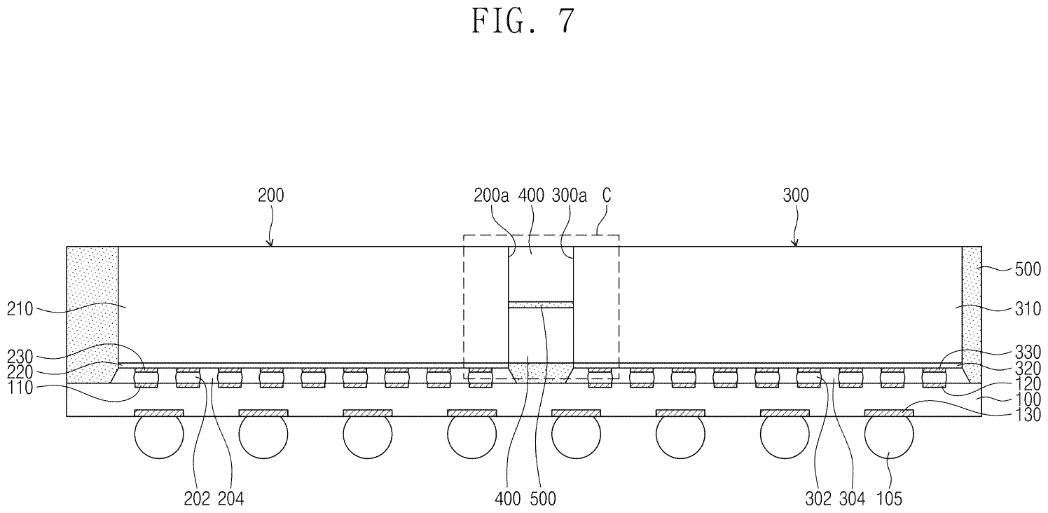

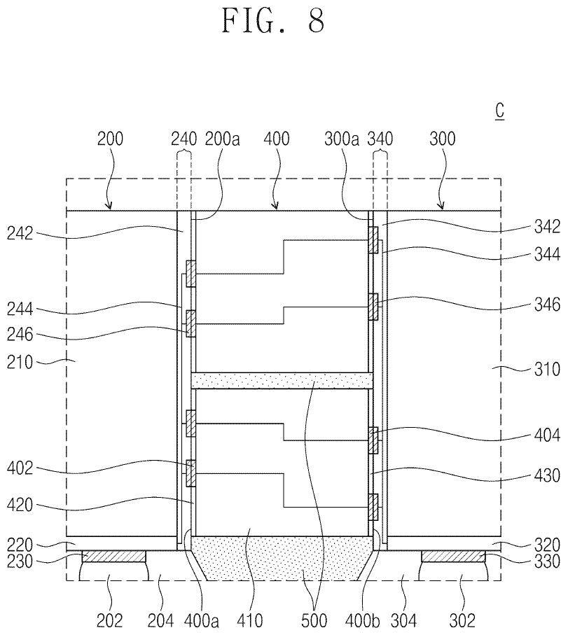

FIG. 7 illustrates a cross-sectional view showing a semiconductor package according to an example embodiment of the present inventive concepts. FIG. 8 illustrates an enlarged view showing section C of FIG. 7, according to an example embodiment.

Referring to FIGS. 7 and 8, a plurality of bridge chips 400 may be provided between the first semiconductor chip 200 and the second semiconductor chip 300. The bridge chips 400 may be spaced apart from each other in a direction parallel to the first lateral surface 200a of the first semiconductor chip 200 or the second lateral surface 300a of the second semiconductor chip 300. FIG. 7 depicts that the bridge chips 400 are spaced apart from each other in a direction perpendicular to the top surface of the substrate 100, but the present inventive concepts are not limited thereto. According to some example embodiments, the bridge chips 400 may be spaced apart from each other in a direction parallel to the top surface of the substrate 100. Each of the bridge chips 400 may have a wiring section 410, a first protection layer 420 and a second protection layer 430 that cover opposite surfaces of the wiring section 410, a first connection pad 402, and a second connection pad 404.

Each of the bridge chips 400 may be bonded to the first semiconductor chip 200. For example, the first connection pads 402 of the bridge chips 400 may be connected to the first chip pads 246.

Each of the bridge chips 400 may be bonded to the second semiconductor chip 300. For example, the second connection pads 404 of the bridge chips 400 may be connected to the second chip pads 346.

The first semiconductor chip 200 and the second semiconductor chip 300 may be electrically connected to each other through the first lateral wiring layer 240 of the first semiconductor chip 200, the bridge chips 400, and the second lateral wiring layer 340 of the second semiconductor chip 300.

On the top surface of the substrate 100, the molding layer 500 may surround the first semiconductor chip 200, the second semiconductor chip 300, and the bridge chips 400. The molding layer 500 may fill a space between the substrate 100 and the bridge chips 400 and a space between the bridge chips 400.

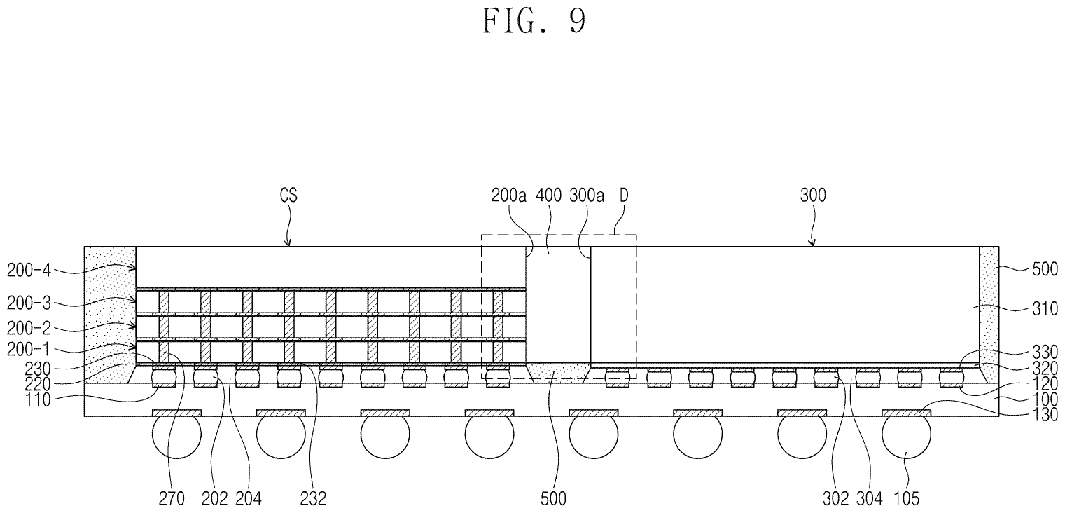

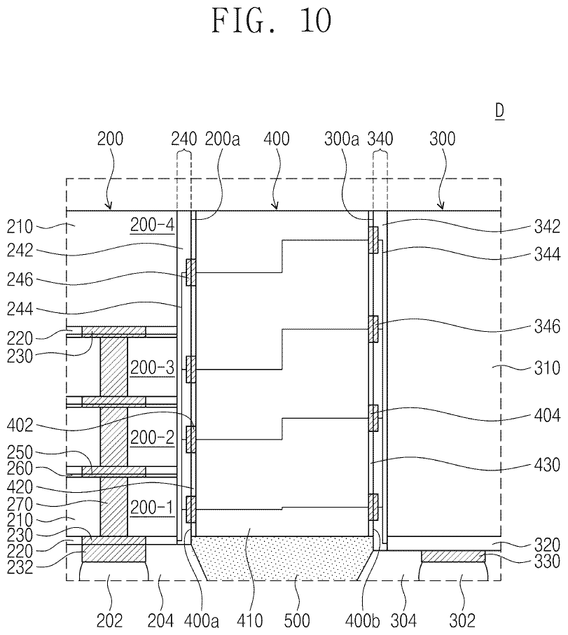

FIG. 9 illustrates a cross-sectional view showing a semiconductor package according to an example embodiments of the present inventive concepts. FIG. 10 illustrates an enlarged view showing section D of FIG. 9, according to an example embodiment.

Referring to FIGS. 9 and 10, a semiconductor package may include a chip stack CS instead of the first semiconductor chip 200 of FIG. 1.

The second semiconductor chip 300 may be disposed on the substrate 100. A second semiconductor chip 300 may include a logic chip. For example, the second semiconductor chip 300 may include an application specific integrated circuit (ASIC). For example, the second semiconductor chip 300 may act as a non-memory chip such as an application processor (AP).

The chip stack CS may be disposed on the substrate 100. The chip stack CS may be disposed horizontally spaced apart from the second semiconductor chip 300. The chip stack CS may include a plurality of third semiconductor chips 200-1, 200-2, 200-3, and 200-4. The third semiconductor chips 200-1, 200-2, 200-3, and 200-4 may be of the same type. For example, the third semiconductor chips 200-1, 200-2, 200-3, and 200-4 may be memory chips. For example, the third semiconductor chips 200-1, 200-2, 200-3, and 200-4 may be DRAM, NAND Flash, NOR Flash, PRAM, ReRAM, or MRAM. The chip stack may be a high bandwidth memory (HBM) configured to include a plurality of stacked chips. For example, the third semiconductor chips 200-1, 200-2, 200-3, and 200-4 may be sequentially stacked on the substrate 100. In the present example embodiment, it is explained that the chip stack CS includes four third semiconductor chips 200-1, 200-2, 200-3, and 200-4, but the present inventive concepts are not limited thereto. According to some example embodiments, the chip stack CS may include more than four third semiconductor chips or may include three or less than three third semiconductor chips. A top surface of the chip stack CS, or a top surface of an uppermost one 200-4 of the third semiconductor chips 200-1, 200-2, 200-3, and 200-4, may be located at the same level as that of a top surface of the second semiconductor chip 300.

Each of the third semiconductor chips 200-1, 200-2, 200-3, and 200-4 may have a configuration the same as or substantially similar to that of the first semiconductor chip 200 discussed with reference to FIGS. 1 to 8. For example, each of the third semiconductor chips 200-1, 200-2, 200-3, and 200-4 may include a first semiconductor substrate 210, a first circuit layer 220, a first lower pad 230, and a first lateral wiring layer 240. A bottom surface of the first lower pad 230 may be substantially flat and coplanar with that of the first circuit layer 220. The third semiconductor chips 200-1, 200-2, and 200-3 except the uppermost third semiconductor chip 200-4 may each include a first upper pad 250, a chip upper protection layer 260, and a chip through electrode 270. The first upper pad 250 may be provided on a top surface of the first semiconductor substrate 210. The chip through electrode 270 may vertically penetrate the first semiconductor substrate 210 to connect the first lower pad 230 and the first upper pad 250 to each other. On the top surface of the first semiconductor substrate 210, the chip upper protection layer 260 may surround the first upper pad 250. A top surface of the first upper pad 250 may be substantially flat and coplanar with that of the chip upper protection layer 260.

The third semiconductor chips 200-1, 200-2, 200-3, and 200-4 may be sequentially mounted on the substrate 100. The same method may be employed to mount the third semiconductor chips 200-1, 200-2, 200-3, and 200-4 of the chip stack CS. Regarding the mounting of the third semiconductor chips 200-1, 200-2, 200-3, and 200-4, the following will describe in detail the mounting of a lowermost third semiconductor chip 200-1 (referred to hereinafter as a first chip) and its overlying third semiconductor chip 200-2 (referred to hereinafter as a second chip).

The second chip 200-2 may be disposed on the first chip 200-1. The first upper pads 250 of the first chip 200-1 may be vertically aligned with the first lower pads 230 of the second chip 200-2. The first chip 200-1 and the second chip 200-2 may be bonded to each other.

On an interface between the first chip 200-1 and the second chip 200-2, the chip upper protection layer 260 of the first chip 200-1 may be bonded to the first circuit layer 220 of the second chip 200-2. In this configuration, the chip upper protection layer 260 and a dielectric pattern of the first circuit layer 220 may constitute a hybrid bonding of oxide, nitride, or oxynitride. For example, the chip upper protection layer 260 and the dielectric pattern of the first circuit layer 220 that are bonded to each other may have a continuous configuration, and an invisible interface may be provided between the chip upper protection layer 260 and the dielectric pattern of the first circuit layer 220. The chip upper protection layer 260 and the dielectric pattern of the first circuit layer 220 may be connected to form a single unitary piece (e.g., an integral piece).

The first chip 200-1 and the second chip 200-2 may be connected to each other. For example, the first chip 200-1 and the second chip 200-2 may be bonded to each other. On an interface between the first chip 200-1 and the second chip 200-2, the first upper pad 250 of the first chip 200-1 may be bonded to the first lower pad 230 of the second chip 200-2. In this configuration, the first upper pad 250 and the first lower pad 230 may constitute an intermetallic hybrid bonding. For example, the first upper pad 250 and the first lower pad 230 that are bonded to each other may have a continuous configuration, and an invisible interface may be provided between the first upper pad 250 and the first lower pad 230. The first upper pad 250 and the first lower pad 230 may be formed of the same material, and no interface may be present between the first upper pad 250 and the first lower pad 230. In this sense, the first upper pad 250 and the first lower pad 230 may be provided as one component. Thus, the first upper pad 250 and the first lower pad 230 may be connected to form a single unitary piece (e.g., an integral piece).

The chip stack CS may be mounted on the substrate 100. A chip stack pad 232 may be provided on the first lower pad 230 of the lowermost one 200-1 of the third semiconductor chips 200-1, 200-2, 200-3, and 200-4. The first connection terminals 202 may be provided on a bottom surface of the chip stack pad 232. The chip stack CS may be aligned on the substrate 100 to allow the first connection terminals 202 to face top surfaces of the first substrate pads 110 included in the substrate 100, and the first connection terminals 202 may be coupled to the first substrate pads 110.

The bridge chip 400 may be provided between the chip stack CS and the second semiconductor chip 300. The bridge chip 400 may have a wiring section 410, a first protection layer 420 and a second protection layer 430 that cover opposite surfaces of the wiring section 410, a first connection pad 402, and a second connection pad 404.

The bridge chip 400 may be bonded to the chip stack CS. For example, the bridge chip 400 may be bonded to each of the third semiconductor chips 200-1, 200-2, 200-3, and 200-4 of the chip stack CS. For example, the first chip pads 246 of the first lateral wiring layers 240 in each of the third semiconductor chips 200-1, 200-2, 200-3, and 200-4 may be connected to corresponding ones of the first connection pads 402 of the bridge chip 400.

The bridge chip 400 may be bonded to the second semiconductor chip 300. For example, the second connection pads 404 of the bridge chip 400 may be connected to the second chip pads 346.

The third semiconductor chips 200-1, 200-2, 200-3, and 200-4 of the chip stack CS may be electrically connected through the bridge chip 400 to the second semiconductor chip 300.

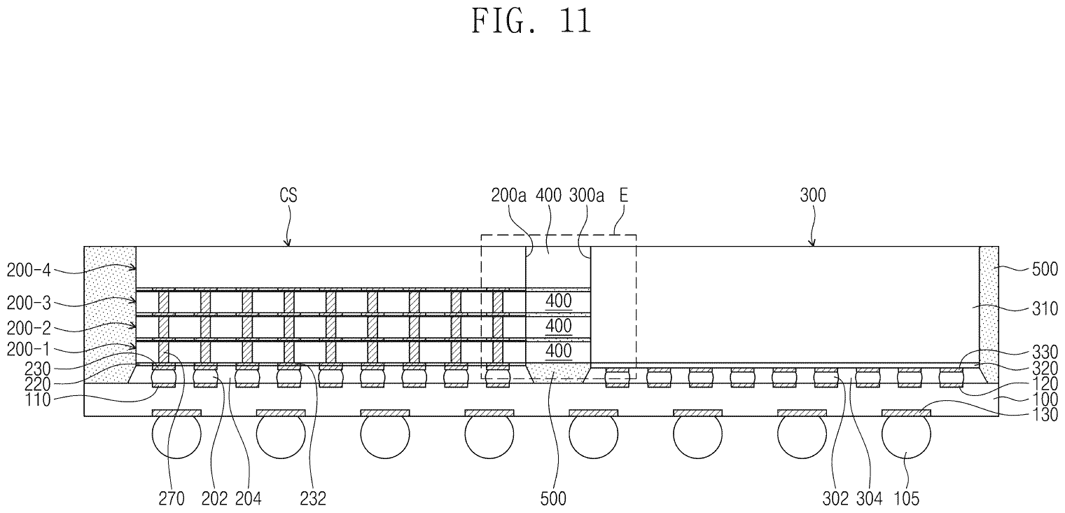

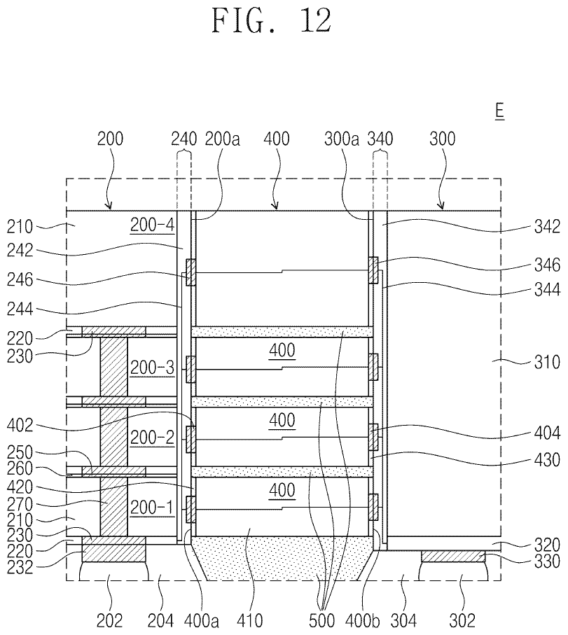

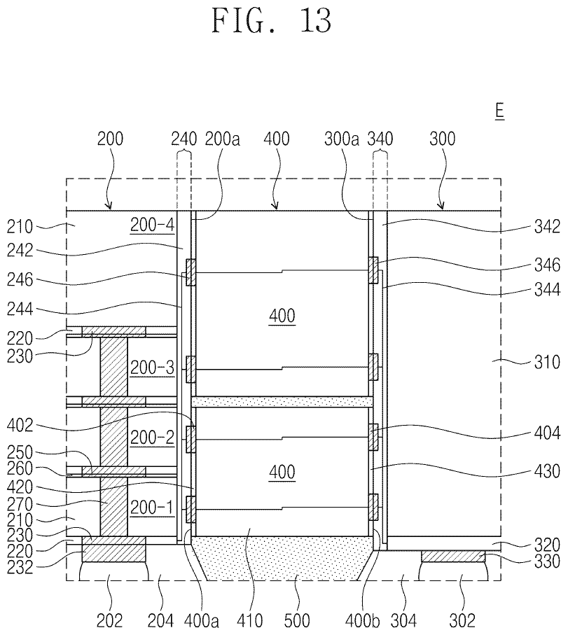

FIG. 11 illustrates a cross-sectional view showing a semiconductor package according to an example embodiments of the present inventive concepts. FIGS. 12 and 13 illustrate enlarged views showing section E of FIG. 11 according to some example embodiments.

Referring to FIGS. 11 and 12, differently from the example embodiments of FIGS. 9 and 10, a plurality of bridge chips 400 may be provided between the chip stack CS and the second semiconductor chip 300. The bridge chips 400 may be spaced apart from each other in a direction parallel to a lateral surface of the chip stack CS or the second lateral surface 300a of the second semiconductor chip 300. For example, each of the bridge chips 400 may be disposed on one side of a corresponding one of the third semiconductor chips 200-1, 200-2, 200-3, and 200-4 included in the chip stack CS. Each of the bridge chips 400 may have a wiring section 410, a first protection layer 420 and a second protection layer 430 that cover opposite surfaces of the wiring section 410, a first connection pad 402, and a second connection pad 404.

The bridge chips 400 may be bonded to the chip stack CS. For example, each of the bridge chips 400 may be bonded to a corresponding one of the third semiconductor chips 200-1, 200-2, 200-3, and 200-4. For example, the first connection pads 402 of the bridge chips 400 may be connected to the first chip pads 246.

Each of the bridge chips 400 may be bonded to the second semiconductor chip 300. For example, the second connection pads 404 of the bridge chips 400 may be connected to the second chip pads 346.

The third semiconductor chips 200-1, 200-2, 200-3, and 200-4 may be electrically connected through the bridge chips 400 to the second semiconductor chip 300.

The example embodiments of FIGS. 11 and 12 depict that each of the bridge chips 400 are disposed on one side of a corresponding one of the third semiconductor chips 200-1, 200-2, 200-3, and 200-4, but the present inventive concepts are not limited thereto. As shown in FIG. 13, at least two of the third semiconductor chips 200-1, 200-2, 200-3, and 200-4 may be connected to one bridge chip 400.

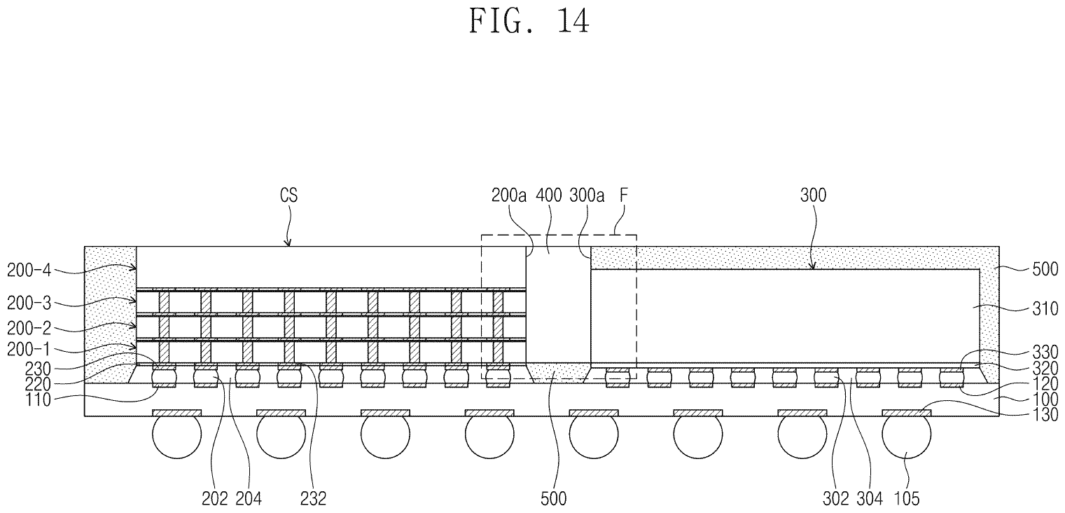

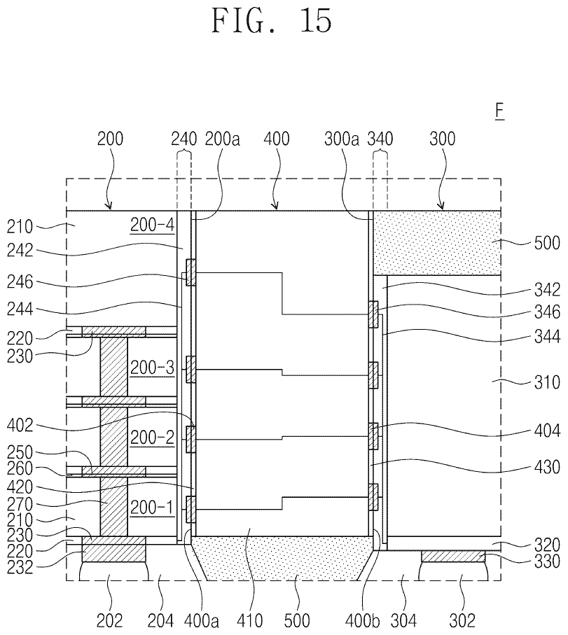

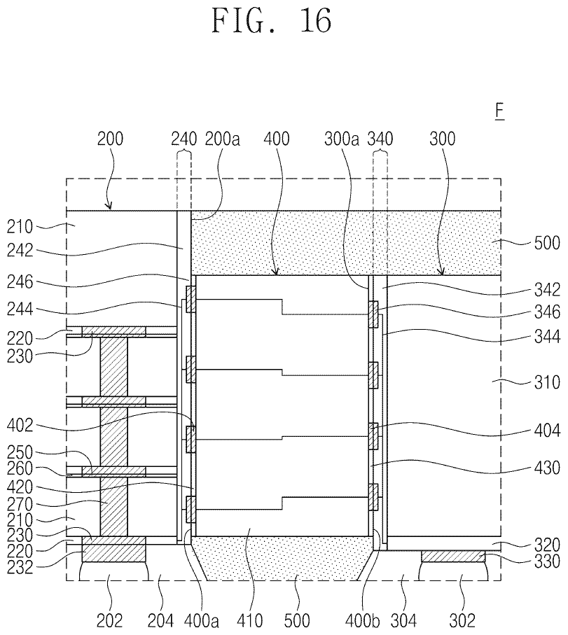

FIG. 14 illustrates a cross-sectional view showing a semiconductor package according to an example embodiment of the present inventive concepts. FIGS. 15 and 16 illustrate enlarged views showing section F of FIG. 14, according to some example embodiments.

Referring to FIGS. 14 and 15, differently from the example embodiments of FIGS. 9 and 10, a top surface of the chip stack CS, or a top surface of an uppermost one 200-4 of the third semiconductor chips 200-1, 200-2, 200-3, and 200-4, may be located at a higher level than that of a top surface of the second semiconductor chip 300.

The bridge chip 400 may be provided between the chip stack CS and the second semiconductor chip 300. The bridge chip 400 may have a wiring section 410, a first protection layer 420 and a second protection layer 430 that cover opposite surfaces of the wiring section 410, a first connection pad 402, and a second connection pad 404.

The bridge chip 400 may be bonded to the chip stack CS. For example, the bridge chip 400 may be bonded to each of the third semiconductor chips 200-1, 200-2, 200-3, and 200-4 of the chip stack CS. For example, the first chip pads 246 of the first lateral wiring layers 240 in each of the third semiconductor chips 200-1, 200-2, 200-3, and 200-4 may be connected to the first connection pads 402 of the bridge chip 400. In this case, an uppermost end of the bridge chip 400 may be located at the same level as that of an uppermost end of the chip stack CS. For example, the chip stack CS may be in contact with an entirety of the first surface 400a of the bridge chip 400.

The bridge chip 400 may be bonded to the second semiconductor chip 300. For example, the second connection pads 404 of the bridge chip 400 may be connected to the second chip pads 346. The uppermost end of the bridge chip 400 may be located at a higher level than that an uppermost end of the second semiconductor chip 300. For example, the second semiconductor chip 300 may be in contact with a portion of the second surface 400b of the bridge chip 400.

In some example embodiments, as shown in FIG. 16, the uppermost end of the bridge chip 400 may be located at the same level as that of the uppermost end of the second semiconductor chip 300. For example, the second semiconductor chip 300 may be in contact with an entirety of the second surface 400b of the bridge chip 400. The uppermost end of the bridge chip 400 may be located at a lower level as that of the uppermost end of the chip stack CS. For example, the chip stack CS may be in contact with an entirety of the first surface 400a of the bridge chip 400.

The third semiconductor chips 200-1, 200-2, 200-3, and 200-4 of the chip stack CS may be electrically connected through the bridge chip 400 to the second semiconductor chip 300.

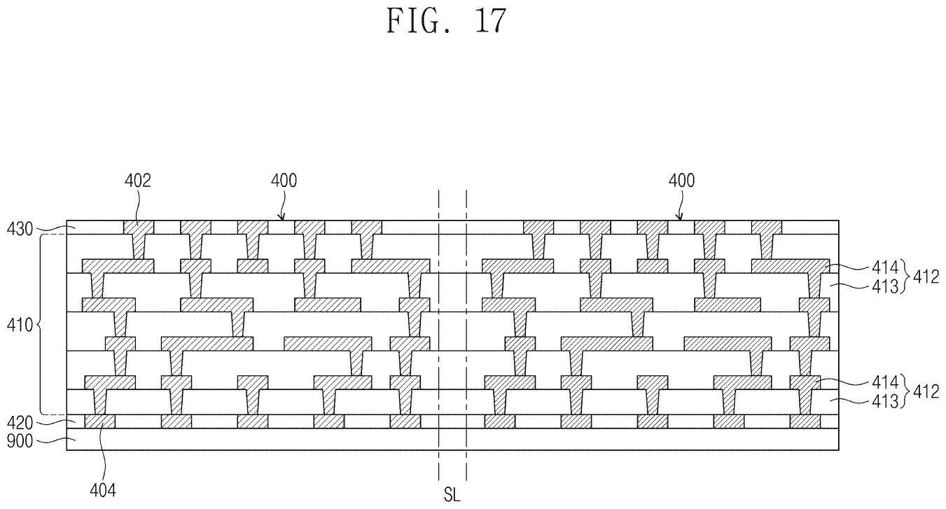

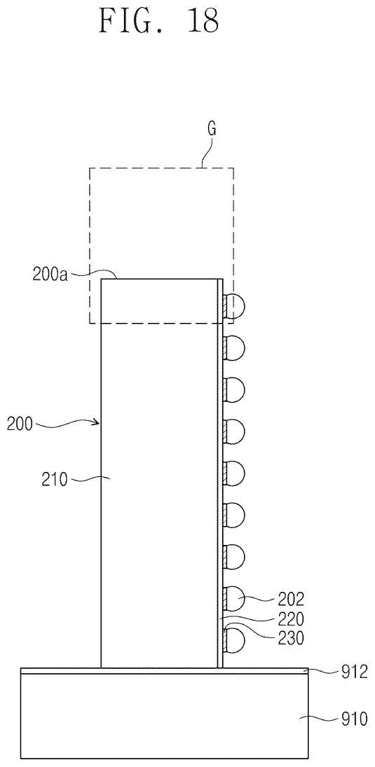

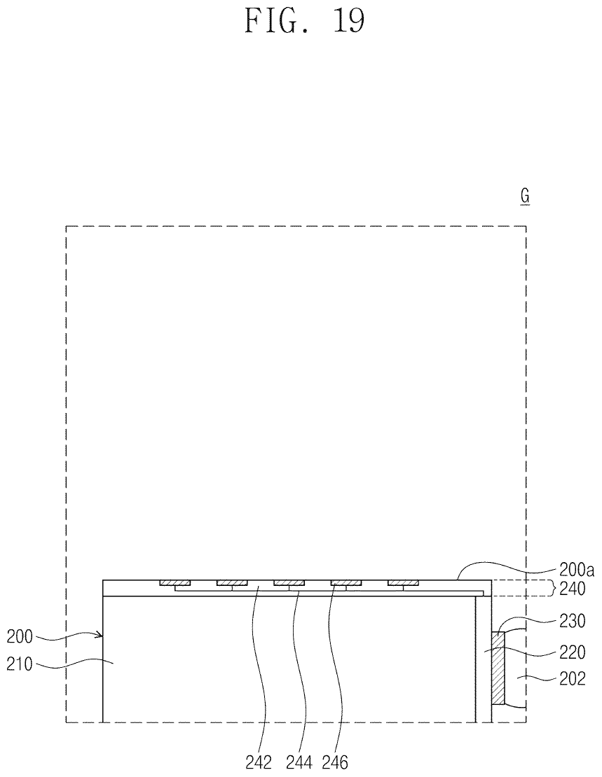

FIGS. 17 to 24 illustrate cross-sectional views showing a method of fabricating a semiconductor package according to an example embodiment of the present inventive concepts. FIGS. 17, 18, 20, 22, and 24 illustrate cross-sectional views showing the method of fabricating a semiconductor package. FIGS. 19, 21, and 23 illustrate enlarged views showing section G of FIGS. 18, 20, and 22, respectively.

Referring to FIG. 17, a first carrier substrate 900 may be provided. The first carrier substrate 900 may be a dielectric substrate including glass or polymer, or may be a conductive substrate including metal. A first adhesive member may be provided on a top surface of the first carrier substrate 900. For example, the first adhesive member may include a glue tape.

A first protection layer 420 may be formed on the first carrier substrate 900. The first protection layer 420 may include a dielectric polymer or a photo-imageable dielectric (PID).

First connection pads 402 may be formed in the first protection layer 420. For example, the first protection layer 420 may be patterned to form openings for forming the first connection pads 402, and a seed layer conformally formed in the openings may be used as a seed to perform a plating process to form the first connection pads 402 that fill the openings.

For another example, a sacrificial layer may be formed on a seed layer formed on the first carrier substrate 900, the sacrificial layer may be patterned to form openings for forming the first connection pads 402, and the seed layer in the openings may be used as a seed to perform a plating process to form the first connection pads 402 that fill the openings. Afterwards, the sacrificial layer may be removed, and the first connection pads 402 may be used as a mask to pattern the seed layer. The first protection layer 420 may be formed on the first carrier substrate 900 to surround the first connection pads 402.

A dielectric pattern 413 may be formed on the first protection layer 420. The dielectric pattern 413 may be formed by a coating process such as spin coating or slit coating. The dielectric pattern 413 may include photo-imageable dielectrics (PID), silicon oxide (SiO), silicon nitride (SiN), silicon oxynitride (SiON), or dielectric polymers.

Openings may be formed in the dielectric pattern 413 to expose the first connection pads 402 and/or horizontally extending trenches may be formed in the dielectric pattern 413. A conductive layer may be formed on the dielectric pattern 413. The conductive layer may fill the openings and/or the trenches, and may cover a top surface of the dielectric pattern 413. The conductive layer may be formed by performing an electroplating process in which a seed layer conformally covering the dielectric pattern 413 is used as a seed. The conductive layer may include metal such as copper, and may extend onto the top surface of the dielectric pattern 413.

The conductive layer may undergo a planarization process to form a wiring pattern 414. The planarization process may include, for example, a chemical mechanical polishing (CMP) process. The planarization process may continue until the top surface of the dielectric pattern 413 is exposed. As such, it may be possible to form one wiring layer 412 having the dielectric pattern 413 and the wiring pattern 414.

The processes discussed above may be repeatedly performed to form a plurality of wiring layers 412. For example, another dielectric pattern 413 may be formed on a lowermost wiring layer 412, an opening may be formed on the dielectric pattern 413 to expose the wiring pattern 414 of the lowermost wiring layer 412, a conductive layer may be formed on the dielectric pattern 413 to fill the opening, and the conductive layer may undergo a planarization process. The wiring pattern 414 of an uppermost wiring layer 412 may have a head part that corresponds to the first connection pads 402. A wiring section 410 may be constituted by the wiring layers 412 that are stacked on each other.

A second protection layer 430 may be formed on the uppermost wiring layer 412. The second protection layer 430 may be formed by a coating process such as spin coating or slit coating. The second protection layer 430 may include a photo-imageable dielectric (PID). For example, the photo-imageable dielectric may include at least one selected from photosensitive polyimide (PI), polybenzoxazole (PBO), phenolic polymers, and benzocyclobutene polymers.

Afterwards, the first protection layer 420, the wiring layers 412, and the second protection layer 430 may undergo a separation process along a sawing line SL to form bridge chips 400 that are separated from each other.

Referring to FIGS. 18 and 19, a second carrier substrate 910 may be provided. The second carrier substrate 910 may be a dielectric substrate including glass or polymer, or may be a conductive substrate including metal. A second adhesive member 912 may be provided on a top surface of the second carrier substrate 910. For example, the second adhesive member 912 may include a glue tape.

A first semiconductor chip 200 may be provided. The first semiconductor chip 200 may be the first semiconductor chip 200 discussed with reference to FIGS. 1 to 8. For example, the first semiconductor chip 200 may include a first semiconductor substrate 210, a first circuit layer 220, a first lower pad 230, and a first lateral wiring layer 240.

The first semiconductor chip 200 may be attached to the second carrier substrate 910. For example, the first semiconductor chip 200 may have a lateral surface opposite to a first lateral surface 200a thereof, and the lateral surface may be attached through the second adhesive member 912 to the second carrier substrate 910. Therefore, the first lateral wiring layer 240 of the first semiconductor chip 200 may be directed toward an upper side of the second carrier substrate 910.

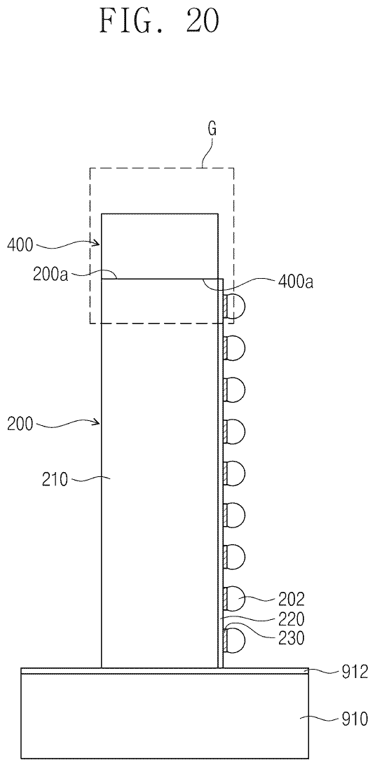

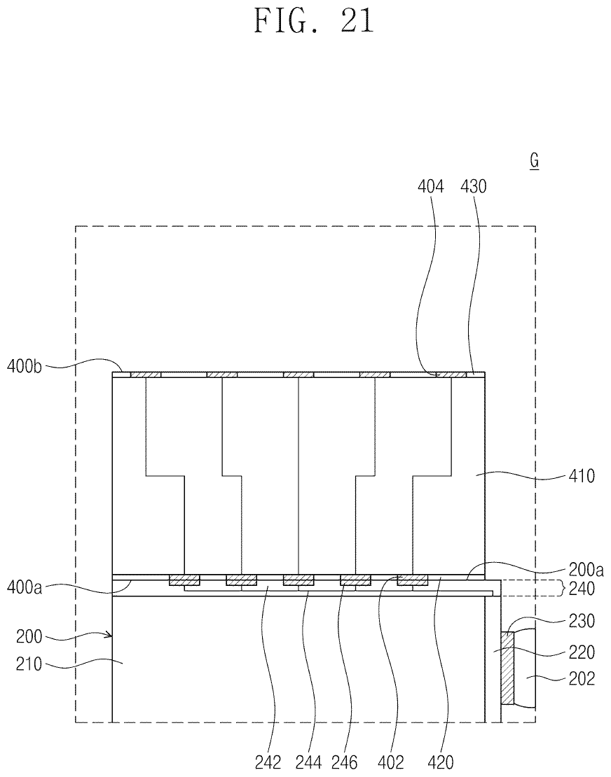

Referring to FIGS. 20 and 21, a bridge chip 400 may be disposed on the first semiconductor chip 200. A first surface 400a of the bridge chip 400 may be directed toward the first lateral surface 200a of the first semiconductor chip 200. Therefore, first chip pads 246 of the first lateral wiring layer 240 included in the first semiconductor chip 200 may be vertically aligned with first connection pads 402 of the bridge chip 400. A first dielectric layer 242 of the first lateral wiring layer 240 included in the first semiconductor chip 200 may be in contact with a first protection layer 420, and the first chip pads 246 of the first lateral wiring layer 240 included in the first semiconductor chip 200 may be in contact with the first connection pads 402 of the bridge chip 400.

An annealing process may be performed on the first semiconductor chip 200 and the bridge chip 400. The annealing process may bond the first chip pads 246 of the first lateral wiring layer 240 included in the first semiconductor chip 200 to the first connection pads 402 of the bridge chip 400. For example, the first chip pad 246 of the first lateral wiring layer 240 included in the first semiconductor chip 200 and the first connection pad 402 of the bridge chip 400 may be connected to form a single unitary piece (e.g., an integral piece). The bonding between the first chip pads 246 and the first connection pads 402 may be automatically performed. For example, the first chip pad 246 and the first connection pad 402 may be formed of the same material (e.g., copper (Cu)), and may be bonded to each other by an intermetallic hybrid bonding process resulting from surface activation at an interface between the first chip pad 246 and the first connection pad 402 that are in contact with each other. The annealing process may bond the first chip pads 246 to the first connection pads 402.

As such, the bridge chip 400 may be bonded to the first semiconductor chip 200. A second surface 400b of the bridge chip 400 may be directed toward an upper side of the second carrier substrate 910.

According to some example embodiments, a chip stack CS may be provided to replace the first semiconductor chip 200. The chip stack CS may correspond to the chip stack CS discussed with reference to FIGS. 9 to 16. The chip stack CS may be attached to the second carrier substrate 910 to allow the first lateral wiring layer 240 of third semiconductor chips 200-1, 200-2, 200-3, and 200-4 to be directed toward an upper side of the second carrier substrate 910. Afterwards, the bridge chip 400 may be bonded to the first lateral wiring layer 240 of the third semiconductor chips 200-1, 200-2, 200-3, and 200-4. The following description will focus on the example embodiment of FIGS. 18 to 21.

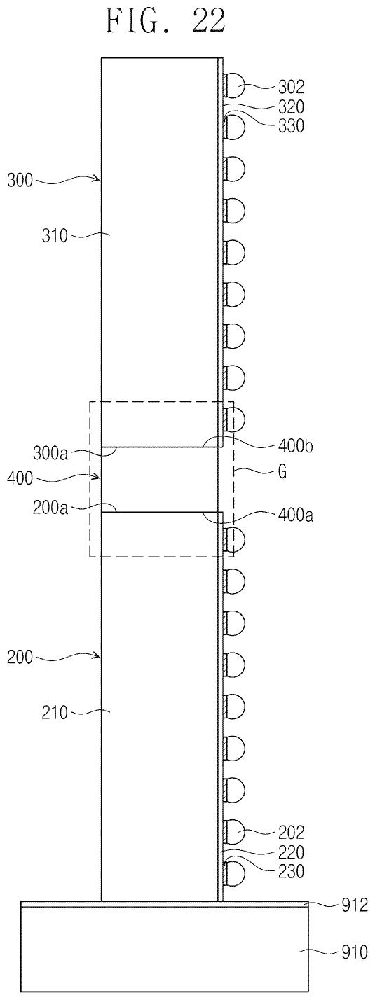

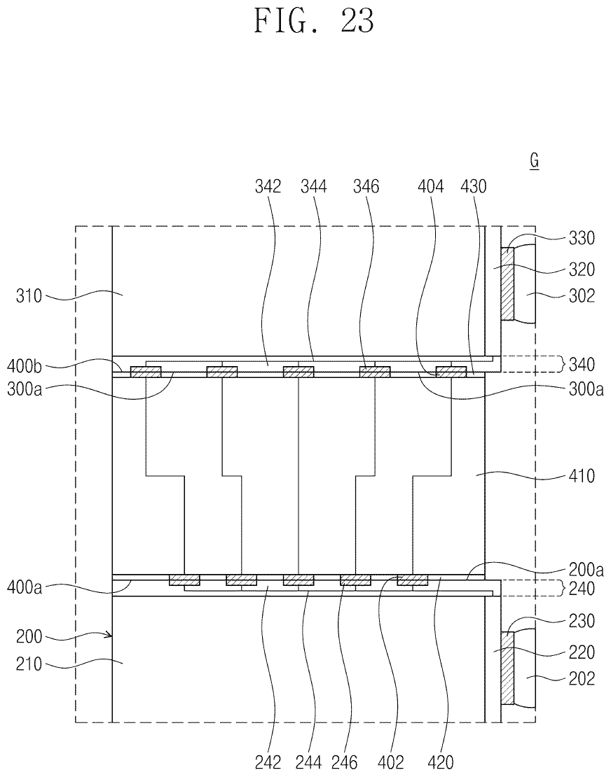

Referring to FIGS. 22 and 23, a second semiconductor chip 300 may be provided. The second semiconductor chip 300 may be the second semiconductor chip 300 discussed with reference to FIGS. 1 to 16. For example, the second semiconductor chip 300 may include a second semiconductor substrate 310, a second circuit layer 320, a second lower pad 330, and a second lateral wiring layer 340.

The second semiconductor chip 300 may be disposed on the bridge chip 400. A second lateral surface 300a of the second semiconductor chip 300 may be directed toward the second surface 400b of the bridge chip 400. Therefore, second connection pads 404 of the bridge chip 400 may be vertically aligned with second chip pads 346 of the second lateral wiring layer 340 included in the second semiconductor chip 300. A second protection layer 430 of the bridge chip 400 may be in contact with a second dielectric layer 342 of the second lateral wiring layer 340 included in the second semiconductor chip 300, and the second connection pads 404 of the bridge chip 400 may be in contact with the second chip pads 346 of the second lateral wiring layer 340 included in the second semiconductor chip 300.

An annealing process may be performed on the bridge chip 400 and the second semiconductor chip 300. The annealing process may bond the second connection pads 404 of the bridge chip 400 to the second chip pads 346 of the second lateral wiring layer 340 included in the second semiconductor chip 300. For example, the second connection pad 404 of the bridge chip 400 and the second chip pad 346 of the second lateral wiring layer 340 included in the second semiconductor chip 300 may be connected to form a single unitary piece (e.g., an integral piece). The bonding between the second connection pads 404 and the second chip pads 346 may be automatically performed. For example, the second connection pad 404 and the second chip pad 346 may be formed of the same material (e.g., copper (Cu)), and may be bonded to each other by an intermetallic hybrid bonding process resulting from surface activation at an interface between the second connection pad 404 and the second chip pad 346 that are in contact with each other. The annealing process may bond the second connection pads 404 to the second chip pads 346.

As such, the second semiconductor chip 300 may be bonded to the bridge chip 400. Therefore, there may be formed a bonding structure of the first semiconductor chip 200, the bridge chip 400, and the second semiconductor chip 300.

Thereafter, the second carrier substrate 910 and the second adhesive member 912 may be removed.

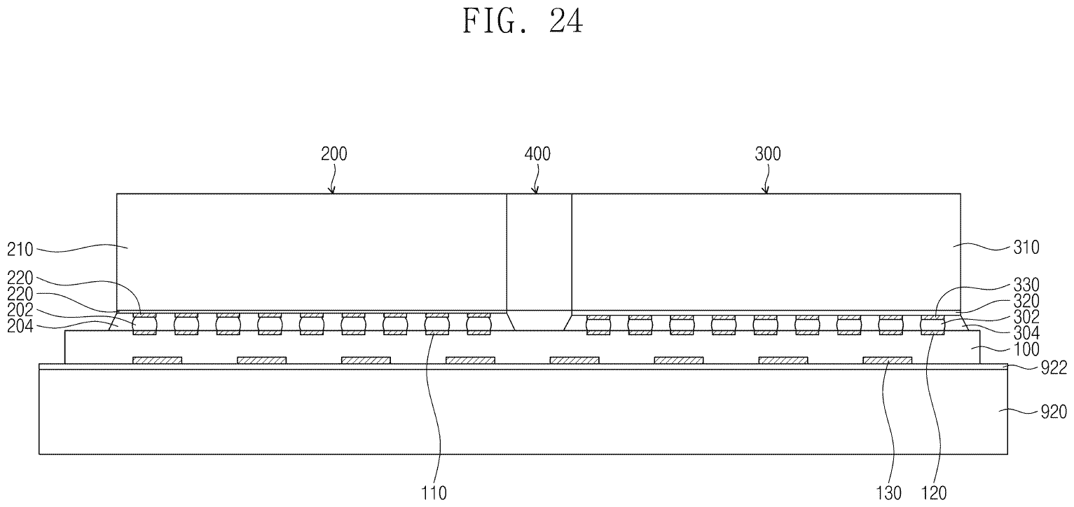

Referring to FIG. 24, a third carrier substrate 920 may be provided. The third carrier substrate 920 may be a dielectric substrate including glass or polymer, or may be a conductive substrate including metal. A third adhesive member 922 may be provided on a top surface of the third carrier substrate 920. For example, the third adhesive member 922 may include a glue tape.

A substrate 100 may be provided. The substrate 100 may be attached through the third adhesive member 922 to the third carrier substrate 920. The substrate 100 may correspond to the substrate 100 discussed with reference to FIGS. 1 to 16.

The first semiconductor chip 200 and the second semiconductor chip 300 may be mounted on the substrate 100. For example, first connection terminals 202 may be provided on the first lower pads 230 of the first semiconductor chip 200, and second connection terminals 302 may be provided on the second lower pads 330 of the second semiconductor chip 300. The bonding structure of the first semiconductor chip 200, the second semiconductor chip 300, and the bridge chip 400 may be aligned to allow the first connection terminals 202 to rest on the first substrate pads 110 and the second connection terminals 302 to rest on the second substrate pads 120, and thereafter a reflow process may be performed to connect the first connection terminals 202 to the first substrate pads 110 and the second connection terminals 302 to the second substrate pads 120.

Referring back to FIG. 1, a molding layer 500 may be formed on the substrate 100. For example, a molding material may be coated on a top surface of the substrate 100 so as to encapsulate the first semiconductor chip 200, the bridge chip 400, and the second semiconductor chip 300. The molding material may be cured to form the molding layer 500. The molding layer 500 may expose or cover a top surface of the first semiconductor chip 200, a top surface of the bridge chip 400, and a top surface of the second semiconductor chip 300.

After that, the third carrier substrate 920 and the third adhesive member 922 may be removed.

In a semiconductor package according to some example embodiments of the present inventive concepts, an electrical connection between a first semiconductor chip and a second semiconductor chip may be accomplished not through a substrate, but through a bridge chip that is interposed between and directly bonded to the first semiconductor chip and the second semiconductor chip. Therefore, a length of the electrical connection between the first semiconductor chip and the second semiconductor chip may be reduced, and electrical properties of the semiconductor package may be improved. The substrate may include no connection line that connects the first semiconductor chip and the second semiconductor chip to each other, and thus the substrate may have a reduced thickness. The semiconductor package may thus have a smaller thickness and a more compact size.

In addition, as the bridge chip is interposed between the first semiconductor chip and the second semiconductor chip, the bridge chip may block heat generated from the first semiconductor chip or the second semiconductor chip. Thus, the first semiconductor chip and the second semiconductor chip may not be affected by the heat generated from the second semiconductor chip and the first semiconductor chip, respectively, and a semiconductor package may have improved thermal stability and enhanced driving stability.

Moreover, because both of the first semiconductor chip and the second semiconductor chip are directly bonded to the bridge chip, the first semiconductor chip and the second semiconductor chip may be firmly bonded to each other. Accordingly, the semiconductor package may increase in structural stability.

Although the present inventive concepts have been described in connection with some example embodiments of the present inventive concepts illustrated in the accompanying drawings, it will be understood by one of ordinary skill in the art that variations in form and detail may be made therein without departing from the spirit and essential feature of the present inventive concepts. The above disclosed example embodiments should thus be considered illustrative and not restrictive.

1. A semiconductor package, comprising:
a substrate;
a first semiconductor chip and a second semiconductor chip that are mounted on the substrate; and
a bridge chip between a first lateral surface of the first semiconductor chip and a second lateral surface of the second semiconductor chip,
wherein the first semiconductor chip and the second semiconductor chip are electrically connected through the bridge chip,
wherein the first semiconductor chip includes a first chip pad on the first lateral surface,
wherein the bridge chip includes a first connection pad on a first surface of the bridge chip,
wherein the first lateral surface of the first semiconductor chip and the first surface of the bridge chip are in contact with each other, and
wherein the first chip pad and the first connection pad include a same material and are bonded to each other to constitute a first integral piece.

2. The semiconductor package of claim 1, wherein the first semiconductor chip includes:
a first circuit layer on a bottom surface of the first semiconductor chip, the first circuit layer having a first integrated circuit of the first semiconductor chip; and
a first lateral wiring layer on the first lateral surface of the first semiconductor chip and connected to the first circuit layer, and
wherein the first chip pad is a portion of the first lateral wiring layer.

3. The semiconductor package of claim 1, wherein
the second semiconductor chip includes a second chip pad on the second lateral surface,
the bridge chip includes a second connection pad on a second surface of the bridge chip, the second surface being opposite to the first surface,
the second lateral surface of the second semiconductor chip and the second surface of the bridge chip are in contact with each other, and
the second chip pad and the second connection pad include a same material and are bonded to each other to constitute a second integral piece.

4. The semiconductor package of claim 3, wherein the second semiconductor chip includes:
a second circuit layer on a bottom surface of the second semiconductor chip, the second circuit layer having a second integrated circuit of the second semiconductor chip; and
a second lateral wiring layer on the second lateral surface of the second semiconductor chip and connected to the second circuit layer, and
wherein the second chip pad is a portion of the second lateral wiring layer.

5. The semiconductor package of claim 1, wherein the bridge chip is a redistribution substrate having a plurality of wiring layers that are stacked in a direction perpendicular to the first surface.

6. The semiconductor package of claim 1, wherein the bridge chip includes:
a core layer parallel to the first surface; and
a via penetrating the core layer and connected to the first connection pad.

7. The semiconductor package of claim 1, wherein an uppermost end of the bridge chip is at a level same as or higher than a level of a top surface of one of the first semiconductor chip and the second semiconductor chip.

8. The semiconductor package of claim 1, wherein the first semiconductor chip and the second semiconductor chip are in a face-down state on the substrate.

9. The semiconductor package of claim 1, wherein the first semiconductor chip and the second semiconductor chip are flip-chip mounted on the substrate.

10. The semiconductor package of claim 1, wherein
the first chip pad of the first semiconductor chip includes a plurality of first chip pads,
the bridge chip includes a plurality of bridge chips, and
the bridge chips are spaced apart from each other on the first lateral surface of the first semiconductor chip.

11. The semiconductor package of claim 10, wherein the bridge chips are between and electrically connect the first semiconductor chip and the second semiconductor chip.

12. The semiconductor package of claim 1, wherein
the first semiconductor chip includes a plurality of first semiconductor chips vertically stacked on the substrate,
the bridge chip includes a plurality of bridge chips, and the first connection pad of each of the bridge chips is bonded to the first chip pad of a corresponding one of the first semiconductor chips, and
each of the bridge chips electrically connects a corresponding one of the first semiconductor chips to the second semiconductor chip.

13-14. (canceled)

15. A semiconductor package, comprising:
a substrate;
a chip stack on the substrate;
a first semiconductor chip on the substrate and spaced apart from the chip stack;
a bridge chip interposed between and electrically connecting the chip stack and the first semiconductor chip; and
a molding layer on the substrate and surrounding the chip stack, the first semiconductor chip, and the bridge chip,
wherein the chip stack includes a plurality of second semiconductor chips that are stacked on the substrate,
wherein the bridge chip is in direct contact with the first semiconductor chip and the second semiconductor chips, and
wherein a lowermost end of the bridge chip is at a level higher than a level of a top surface of the substrate.

16. The semiconductor package of claim 15, wherein
the first semiconductor chip includes,
a first lateral surface in contact with a first surface of the bridge chip, and
a first chip pad on the first lateral surface, and
wherein each of the second semiconductor chips includes,
a second lateral surface in contact with a second surface of the bridge chip, and
a second chip pad on the second lateral surface.

17. The semiconductor package of claim 16, wherein
the bridge chip includes,
a first connection pad on the first surface, and
a plurality of second connection pads on the second surface,
the first connection pad is bonded to the first chip pad, the first connection pad and the first chip pad including a same material and constituting a first integral piece, and
each of the second connection pads is bonded to the second chip pad of a corresponding one of the second semiconductor chips, each of the second connection pads and the second chip pad of a corresponding one of the second semiconductor chips including a same material and constituting a second integral piece.

18. The semiconductor package of claim 15, wherein
the first semiconductor chip includes.
a first circuit layer on a bottom surface of the first semiconductor chip, the first circuit layer having a first integrated circuit of the first semiconductor chip, and
a first lateral wiring layer on a lateral surface of the first semiconductor chip and connected to the first circuit layer, and
the first lateral wiring layer is bonded to the bridge chip.

19. The semiconductor package of claim 15, wherein
each of the second semiconductor chips includes,
a second circuit layer on a bottom surface of the second semiconductor chip, the second circuit layer having a second integrated circuit of the second semiconductor chip, and
a second lateral wiring layer on a lateral surface of the second semiconductor chip and connected to the second circuit layer, and
the second lateral wiring layer is bonded to the bridge chip.

20-21. (canceled)

22. The semiconductor package of claim 15, wherein an uppermost end of the bridge chip is at a level the same as or higher than a level of a top surface of the first semiconductor chip.

23. (canceled)

24. The semiconductor package of claim 15, wherein the first semiconductor chip and the chip stack are flip-chip mounted on the substrate.

25-28. (canceled)

29. A semiconductor package, comprising:
a substrate;
a first semiconductor chip on the substrate, the first semiconductor chip including,
a first circuit layer on a bottom surface of the first semiconductor chip and having a first integrated circuit of the first semiconductor chip, and
a first lateral wiring layer on a first lateral surface of the first semiconductor chip and connected to the first circuit layer;
a second semiconductor chip on the substrate, the second semiconductor chip including,
a second circuit layer on a bottom surface of the second semiconductor chip and having a second integrated circuit of the second semiconductor chip, and
a second lateral wiring layer on a second lateral surface of the second semiconductor chip and connected to the second circuit layer;
a bridge chip including a first primary surface and a second primary surface, the first primary surface bonded to the first lateral wiring layer, the second primary surface bonded to the second lateral wiring layer; and
a molding layer on the substrate and surrounding the first semiconductor chip, the second semiconductor chip, and the bridge chip,
wherein the first semiconductor chip and the second semiconductor chip are electrically connected through the bridge chip.
